(19) United States
(12) Patent Application Publication
(10) Pub. No.: US 2021/0373690 A1
(43) Pub. Date: Dec. 2, 2021

(54) TOUCH STRUCTURE, MANUFACTURING METHOD THEREOF, AND DISPLAY DEVICE

(71) Applicant: Wuhan China Star Optoelectronics Semiconductor Display Technology Co., Ltd., Wuihan (CN)

(72) Inventor: Ming XIE, Wuhan (CN)

(73) Assignee: Wuhan China Star Optoelectronics Semiconductor Display Technology Co., Ltd., Wuhan (CN)

(21) Appl. No.: 16/638,145

(22) PCT Filed: Dec. 12, 2019
(86) PCT No.: PCT/CN2019/124846

§ 371 Date: Feb. 11, 2020

(30) Foreign Application Priority Data
Nov. 1, 2019 (CN) 201911058261.8

(51) Int. Cl. G06F 3/041; H01L 27/32

(52) U.S. Cl. CPC G06F 3/0412; G06F 2203/04102; G06F 2203/04103; H01L 27/323

(57) ABSTRACT

Disclosed are a touch structure, a manufacturing method thereof, and a display device. The touch structure includes an insulating layer defining a plurality of grooves on one surface of the insulating layer; a metal mesh having a plurality of first traces arranged in parallel to each other and a plurality of second traces arranged in parallel to each other, wherein the first traces and the second traces are intersected, the metal mesh is disposed on the surface of the insulation layer defining the grooves, the grooves are defined at an intersection of the first traces and the second traces, the first traces are disposed inside the grooves, and the second traces are disposed above the grooves; and an insulating filling layer filled in the grooves and configured to insulatingly separate the first traces and the second traces.

### FIELD OF INVENTION

The present disclosure relates to the field of display technologies, and more particularly to a touch structure, a manufacturing method thereof, and a display device.

### BACKGROUND OF INVENTION

With the rapid development of display technologies in recent years, active matrix organic light emitting diode (AMOLED) flexible displays have attracted much attention. Bendable, and even foldable, fixed curved mobile phones having large-size full-screens will be widely used in the future market. However, poor mechanical reliability of flexible panels with flexible or foldable features is a major obstacle to the mass production of such products. After multiple continuous bendings, material will crack and accelerate the failure of the products, especially occurs in a display touch layer. After multiple bendings, a touch circuit is destroyed to lose a touch function.

Metal mesh technology uses metal materials such as silver and copper to grow on glass or plastic films such as PET to form conductive metal mesh patterns. Resistivity of the metal mesh is lower than ITO, usually less than 10 Ω·m, which can realize roll-to-roll production. The mesh has good bending resistance and can be used for flexible folding devices. However, an intersection of the mesh and an included angle of the metal will affect strength of an overall flexible touch system. Reducing such an included angle will enhance an anti-folding performance of the touch system, and a bending strength of a formed curved metal wire is greater than that of a folding line and a straight line.

### Technical Problem

To solve the above technical problems, the present invention provides a touch structure, a manufacturing method thereof, and a display device. Grooves are formed in an insulating layer, so that a first traces on a lower layer in a metal mesh form a buffer angle with the insulating layer. Thus, an arc-shaped 3D curved metal mesh is formed to improve an overall flexibility and bending resistance of the metal mesh.

### SUMMARY OF INVENTION

Technical solutions to solve the above issues are that: an embodiment of the present invention provides a touch structure, comprising: an insulating layer defining a plurality of grooves on one surface of the insulating layer; a metal mesh having a plurality of first traces arranged in parallel to each other, a plurality of second traces arranged in parallel to each other, a first touch electrode connected between the first traces, and a second touch electrode connected between the second traces, wherein the first traces and the second traces are intersected; the metal mesh is disposed on the surface of the insulation layer defining the grooves, the grooves are defined at an intersection of the first traces and the second traces, the first traces are disposed inside the grooves, and the second traces are disposed above the grooves; and an insulating filling layer filled in the grooves and configured to insulatingly separate the first traces and the second traces.

In an embodiment of the present invention, a cross section of each of the grooves is arc-shaped.

In an embodiment of the present invention, an angle is included between each of the first traces and each of the second traces, and the angle ranges from 60° to 120°.

In an embodiment of the present invention, structures of the first traces and the second traces are each a multilayer metal structure or a single-layer metal structure, and the multilayer metal structure comprises a titanium-aluminum-titanium structure; the single-layer metal structure comprises a silver nanowire structure or a copper wire structure.

In an embodiment of the present invention, the insulating layer is a flexible inorganic layer, and material of the insulating layer comprises at least one of silicon nitride and aluminum nitride; the insulating filling layer is a flexible inorganic layer, and material of the insulating filling layer comprises at least one of silicon nitride and aluminum nitride.

In an embodiment of the present invention, the touch structure further comprises a protective layer covering a surface of the metal mesh.

An embodiment of the present invention further provides a method of manufacturing a touch structure, comprising following steps: depositing an insulating material to form an insulating layer; forming a plurality of grooves on one surface of the insulating layer; forming a plurality of first traces arranged in parallel with each other on the surface of the insulating layer defining the grooves, wherein the first traces pass through inside of the grooves; filling an insulating filling material in the grooves to form an insulating filling layer; and forming a plurality of second traces arranged in parallel with each other on the surface of the insulating layer defining the grooves, wherein the second traces are disposed above the grooves and disposed on the insulating filling layer, the first traces and the second traces are intersected, and the first traces and the second traces form a metal mesh.

In an embodiment of the present invention, in the step of forming the grooves, the method comprises: presetting an intersection of the first traces and the second traces on the surface of the insulation layer; taking the intersection of the first traces and the second traces as a center of a circle, bombarding the surface of the insulating layer by an ion beam to form the grooves, and a cross-section of each of the grooves is arc-shaped; and after the step of forming the metal mesh, the method further comprises forming a protective layer on a surface of the metal mesh.

In an embodiment of the present invention, when the surface of the insulating layer is bombarded by the ion beam, the center of the circle for a preset time is first bombarded to form an initial deepest depth and an initial diameter of the grooves; then an ion beam bombardment time is set to gradually decrease as a diameter of the circle increases, such that the ion beam orbits around the center of the circle at a constant velocity, corresponding depths of the grooves on different orbits are bombarded, and the grooves are finally formed with an arc-shaped cross section.

An embodiment of the present invention further provides a display device, comprising: an array substrate; an electroluminescent layer disposed on the array substrate; a thin film encapsulation layer encapsulated on the array substrate and the electroluminescent layer; the above touch structure disposed on the thin film encapsulation layer; a polarizer disposed on the touch structure; and a flexible cover disposed on the polarizer.

### Beneficial Effect

The present invention provides a touch structure, a manufacturing method thereof, and a display device. Grooves are formed in an insulating layer, so that a first traces on a lower layer in a metal mesh form a buffer angle with the insulating layer. Thus, an arc-shaped 3D curved metal mesh is formed to improve an overall flexibility and bending resistance of the metal mesh. This makes flexible devices, such as flexible display devices, easier to fold and better structured. This removes the included angle caused by direct contact between the first traces and the second traces in the metal mesh. This reduces internal stress between the metal meshes and effectively prevents touch failure issues under multiple bendings and high-intensity impacts. This improves quality and performance of flexible devices. The method of the invention is simple, can be used in industrial production, and is widely used in flexible display technology.

### DESCRIPTION OF DRAWINGS

The present invention is further explained below with reference to the drawings and embodiments.

FIG. 1 is a top view of a touch structure according to an embodiment of the present invention, which mainly reflects a positional relationship between a first traces and a second traces.

FIG. 2 is a structural diagram of a groove structure in a method of manufacturing a touch structure according to an embodiment of the present invention, and an arrow in the figure indicates an ion beam.

FIG. 3 is a structural diagram of a method of manufacturing a touch structure according to an embodiment of the present invention after a first traces are formed.

FIG. 4 is a structural diagram of forming an insulating filling layer in a method of manufacturing a touch structure according to an embodiment of the present invention.

FIG. 5 is a structural diagram of a method of manufacturing a touch structure according to an embodiment of the present invention after a second traces is formed.

FIG. 6 is a structural diagram of a method of manufacturing a touch structure according to an embodiment of the present invention after a protective layer is formed, that is, a schematic diagram of an overall touch structure.

FIG. 7 is a structural diagram of a display device according to an embodiment of the present invention.

FIG. 8 is a schematic diagram of a movement orbit of an ion beam in a method of manufacturing a touch structure according to an embodiment of the invention.

### REFERENCE SIGN

100 display device;
1 array substrate; 2 electroluminescent layer;
3 thin film encapsulation layers; 4 touch structure;
5 polarizer; 6 flexible cover;
41 insulating layer; 42 metal mesh;
43 insulating filling layer; 44 protective layer;
45 groove; 421 first trace;
422 second trace; 423 first touch electrode;
424 second touch electrode; 7 ion beam.

### DETAILED DESCRIPTION OF PREFERRED EMBODIMENTS

The following embodiments are described with reference to the accompanying drawings to illustrate specific embodiments in which the present invention can be implemented. The directional terms mentioned in the present invention, such as “up”, “down”, “front”, “rear”, “left”, “right”, “top”, “bottom”, etc., are only for reference to a direction of the accompanying drawings direction. Therefore, the directional terms used are for explaining and understanding the present invention, but not for limiting the present invention.

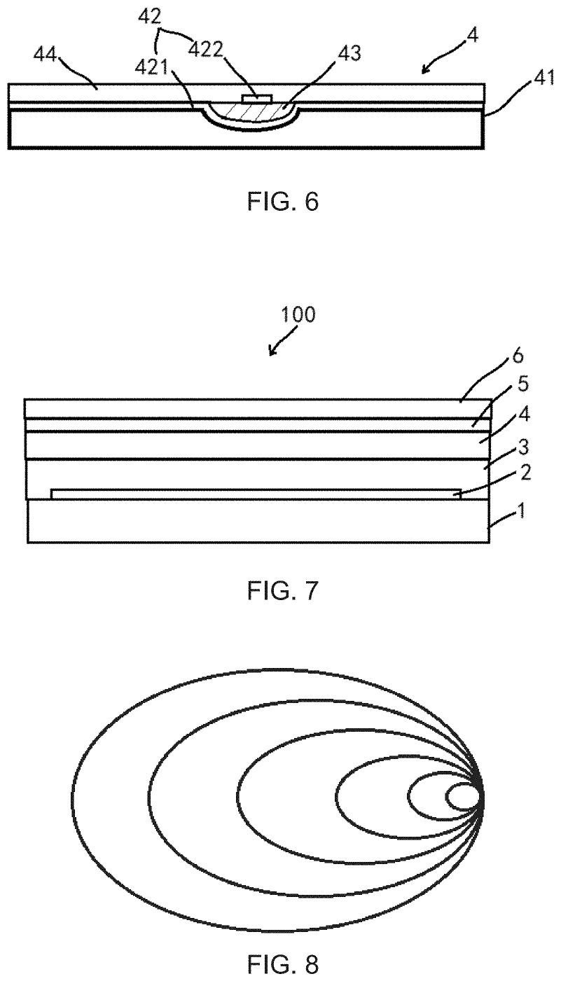

As shown in FIG. 6, in one embodiment, a touch structure 4 of the present invention includes an insulating layer 41, a metal mesh 42, an insulating filling layer 43, and a protective layer 44.

As shown in FIG. 2, one surface of the insulating layer 41 defines a plurality of grooves 45. Only one of the grooves 45 is shown in the figure to clearly show an enlarged structure of the groove 45. In this embodiment, the insulating layer 41 is a flexible inorganic layer, and a material used for the insulating layer 41 includes at least one of silicon nitride and aluminum nitride. A cross section of the groove 45 is arc-shaped.

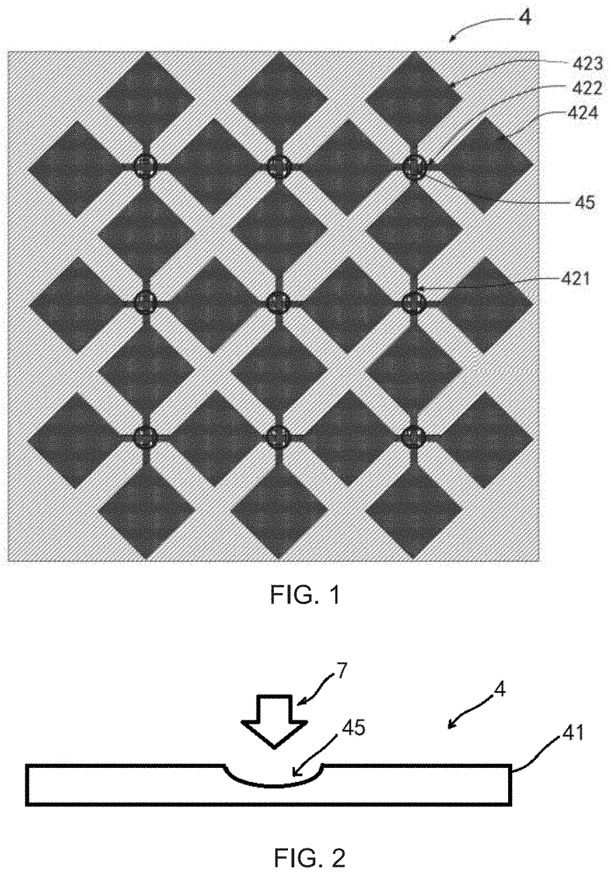

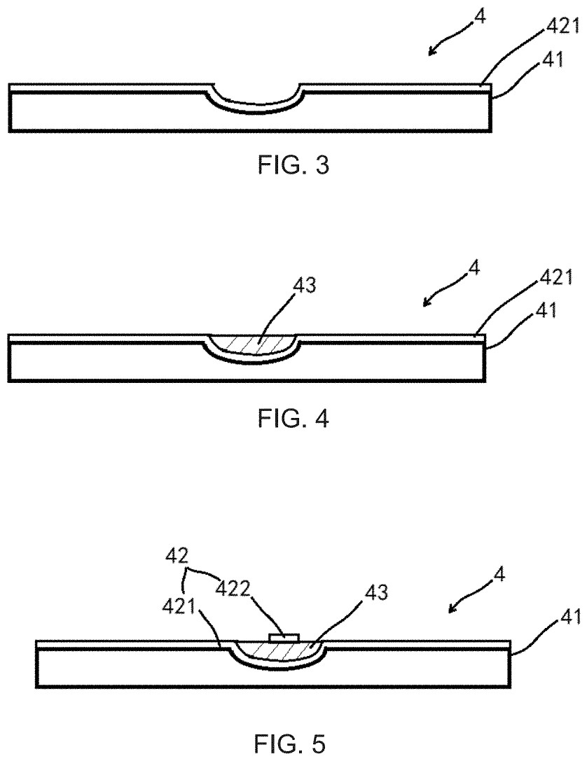

As shown in FIG. 1, FIG. 3, and FIG. 5, the metal mesh 42 has a plurality of first traces 421 arranged in parallel with each other, a plurality of second traces 422 arranged in parallel with each other, a first touch electrode 423 connected between the first traces 421, and a second touch electrode 424 connected between the second traces 422. The first traces 421 and the second traces 422 are intersected. That is, there is an included angle between the first trace 421 and the second trace 422. The included angle ranges from 60° to 120°. In this embodiment, the included angle between the first trace 421 and the second trace 422 is 90°. The metal mesh 42 is disposed on the surface of the insulating layer 41 defining the grooves 45. The grooves 45 are disposed at an intersection of the first traces 421 and the second traces 422. The first traces 421 are disposed inside the grooves 45. The second traces 422 are disposed above the grooves 45. That is, each groove 45 corresponds to an intersection. There is a first trace 421 in each groove 45 and a second trace 422 above each groove 45. Structures of the first trace 421 and the second trace 422 each are a multi-layer metal structure or a single-layer metal structure. The multi-layer metal structure includes a titanium-aluminum-titanium structure. The single-layer metal structure includes a silver nanowire structure or a copper wire structure.

As shown in FIG. 4 to FIG. 6, the insulating filling layer 43 is filled in the grooves 45 to insulatingly separate the first traces 421 and the second traces 422 from each other. The insulating filling layer 43 is a flexible inorganic layer. The material used for the insulating filling layer 43 includes at least one of silicon nitride and aluminum nitride.

As shown in FIG. 6, the protective layer 44 covers a surface of the metal mesh 42. The protective layer 44 is made of organic materials, including OC glue, acrylic, and polyimide.

In order to explain the touch structure 4 more clearly, an embodiment of the present invention also provides a method of manufacturing the touch structure 4, which includes the following steps.

As shown in FIG. 2, the insulating layer 41 is formed by depositing an insulating material. In this embodiment, the insulating layer 41 is directly deposited on the thin film encapsulation layer 3 of the array substrate 1 to form the insulating layer 41. For the array substrate 1 and the thin film encapsulation layer 3, refer to the description of the display device 100 below, and refer to FIG. 7 at the same time.

As shown in FIG. 2, a plurality of grooves 45 are formed on one side of the insulating layer 41. In the step of forming the grooves 45, the method comprises: presetting an intersection of the first traces 421 and the second traces 422 on the surface of the insulation layer 41; taking the intersection of the first traces 421 and the second traces 422 as a center of a circle, bombarding the surface of the insulating layer 41 by an ion beam 7 to form the grooves 45, and a cross-section of each of the grooves 45 is arc-shaped, and its shape may be hemispherical. More specifically, the deposited insulating layer 41 is placed in a vacuum chamber. When the vacuum chamber pressure is 5×10⁻⁴ Pa, argon ion bombardment is used. An ion source uses a cold cathode ion source, and gas is high-purity argon. A control gas flow rate is 15 mL/min (standard state). A bombardment distance between the ion source and the insulating layer 41 is about 20 cm. The ion source discharge voltage is set to 700 V. A discharge current is 500 mA, a lead-out voltage is 1200 V, and a beam current is 50 to 100 mA. Then, the surface of the insulating layer 41 is bombarded by the ion beam 7, that is, the preset time at the center of the circle is first bombarded for a preset time of 15 minutes to form the initial deepest depth and initial diameter of the groove 45. The initial deepest depth is 0.5 μm to 1.5 μm, which is 1 μm in this embodiment. The ion beam 7 has a diameter of 20 nm, and the initial diameter of the groove 45 after bombardment is 200 nm. Then a bombardment time of the ion beam 7 is set to gradually decrease as a diameter of the circle increases, such that the ion beam 7 orbits around the center of the circle at a constant velocity. The bombardment time is different on different orbits, so that the depths of the grooves 45 bombarded by different orbits are different. That is, the depth of the groove 45 away from the center (circle center) is smaller than the depth of the groove 45 near the center (circle center). Finally, a groove 45 having an arc-shaped cross section is formed. The movement orbit of the ion beam 7 is shown in FIG. 8. In this step, the depth of the groove 45 on the insulating layer 41 is changed by changing the sweeping and bombarding time of the ion beam 7, so as to form a preset groove 45 having an arc shape in cross section.

As shown in FIG. 3, the first traces 421 arranged in parallel with each other are formed on the surface of the insulating layer 41 defining the grooves 45. The first traces 421 pass through inside of the grooves 45. In this embodiment, the first traces 421 adopt a single-layer structure. That is, an inkjet printing method is used to form a plurality of parallel first silver nanowires with a diameter of 50 nm. Silver nanowires grow against the surface of the groove 45 and intersect at the center of the groove 45.

As shown in FIG. 4, an insulating filling material is filled in the grooves 45 to form the insulating filling layer 43. In this embodiment, an ink-jet printing method or an inorganic thin film deposition method is used to deposit the insulating filling material on the grooves 45 and the first traces 421. The insulating filling material fills the grooves 45, and then the excess insulating filling material is removed by etching. This exposes the first traces 421 and makes the insulating filling material in the grooves 45 flush with the surface of the grooves 45. The insulating filling layer 43 is formed in the grooves 45.

As shown in FIG. 5, the second traces 422 are formed in parallel with each other on the surface of the insulating layer 41 defining the grooves 45. The second traces 422 are disposed on the insulating filling layer 43 of the grooves 45. The first traces 421 and the second traces 422 are intersected. The first traces 421 and the second traces 422 form the metal mesh 42. In this embodiment, the second traces 422 also adopt a single-layer structure. That is, an inkjet printing method is used to form a plurality of parallel second silver nanowires with a diameter of 50 nm. The silver nanowires grow against the surface of the insulating filling layer 43 in the grooves 45 and intersect at a center of a notch of the groove 45. An intersection angle of 90° is formed between the second trace 422 and the first trace 421.

As shown in FIG. 6, after forming the metal mesh 42, a protective layer 44 is further formed on a surface of the metal mesh 42. First, a layer of protective material is formed on the surface of the metal mesh 42. The protective materials are organic materials, including OC glue, acrylic, and polyimide materials. In this embodiment, OC glue is selected.

As shown in FIG. 7, an embodiment of the present invention also discloses a display device 100 including an array substrate 1, an electroluminescent layer 2, a thin film encapsulation layer 3, a touch structure 4, a polarizer 5, and a flexible cover 6. The electroluminescent layer 2 is disposed on the array substrate 1. The thin film encapsulation layer 3 is encapsulated on the array substrate 1 and the electroluminescent layer 2. The touch structure 4 is disposed on the thin film encapsulation layer 3. The polarizer 5 is disposed on the touch structure 4. The flexible cover 6 is disposed on the polarizer 5.

The main design points of the display device 100 according to the embodiment of the present invention are the touch structure 4 disposed on other components of the display device 100, such as a color filter substrate, will not be described in detail.

The above are only preferred embodiments of the present invention and are not intended to limit the present invention. Any modification, equivalent replacement and improvement made within the spirit and principle of the present invention shall be included in the protection scope of the present invention.

1. A touch structure, comprising:
an insulating layer defining a plurality of grooves on one surface of the insulating layer;
a metal mesh having a plurality of first traces arranged in parallel to each other, a plurality of second traces arranged in parallel to each other, a first touch electrode connected between the first traces, and a second touch electrode connected between the second traces, wherein the first traces and the second traces are intersected; the metal mesh is disposed on the surface of the insulation layer defining the grooves, the grooves are defined at an intersection of the first traces and the second traces, the first traces are disposed inside the grooves, and the second traces are disposed above the grooves; and
an insulating filling layer filled in the grooves and configured to insulatingly separate the first traces and the second traces.

2. The touch structure according to claim 1, wherein a cross section of each of the grooves is arc-shaped.

3. The touch structure according to claim 1, wherein an angle is included between each of the first traces and each of the second traces, and the angle ranges from 60° to 120°.

4. The touch structure according to claim 1, wherein structures of the first traces and the second traces are each a multilayer metal structure or a single-layer metal structure, and the multilayer metal structure comprises a titanium-aluminum-titanium structure; the single-layer metal structure comprises a silver nanowire structure or a copper wire structure.

5. The touch structure according to claim 1, wherein the insulating layer is a flexible inorganic layer, and material of the insulating layer comprises at least one of silicon nitride and aluminum nitride; the insulating filling layer is a flexible inorganic layer, and material of the insulating filling layer comprises at least one of silicon nitride and aluminum nitride.

6. The touch structure according to claim 1, further comprising a protective layer covering a surface of the metal mesh.

7. A method of manufacturing a touch structure, comprising following steps:
depositing an insulating material to form an insulating layer;
forming a plurality of grooves on one surface of the insulating layer;
forming a plurality of first traces arranged in parallel with each other on the surface of the insulating layer defining the grooves, wherein the first traces pass through inside of the grooves;
filling an insulating filling material in the grooves to form an insulating filling layer; and
forming a plurality of second traces arranged in parallel with each other on the surface of the insulating layer defining the grooves, wherein the second traces are disposed above the grooves and disposed on the insulating filling layer, the first traces and the second traces are intersected, and the first traces and the second traces form a metal mesh.

8. The method of manufacturing the touch structure according to claim 7, wherein in the step of forming the grooves, the method comprises:
presetting an intersection of the first traces and the second traces on the surface of the insulation layer;
taking the intersection of the first traces and the second traces as a center of a circle, bombarding the surface of the insulating layer by an ion beam to form the grooves, and a cross-section of each of the grooves is arc-shaped; and
after the step of forming the metal mesh, the method further comprises forming a protective layer on a surface of the metal mesh.

9. The method of manufacturing the touch structure according to claim 8, wherein when the surface of the insulating layer is bombarded by the ion beam, the center of the circle for a preset time is first bombarded to form an initial deepest depth and an initial diameter of the grooves; then an ion beam bombardment time is set to gradually decrease as a diameter of the circle increases, such that the ion beam orbits around the center of the circle at a constant velocity, corresponding depths of the grooves on different orbits are bombarded, and the grooves are finally formed with an arc-shaped cross section.

10. A display device, comprising:
an array substrate;
an electroluminescent layer disposed on the array substrate;
a thin film encapsulation layer encapsulated on the array substrate and the electroluminescent layer;
a touch structure disposed on the thin film encapsulation layer;
a polarizer disposed on the touch structure; and
a flexible cover disposed on the polarizer;
wherein the touch structure comprises:
an insulating layer defining a plurality of grooves on one surface of the insulating layer;
a metal mesh having a plurality of first traces arranged in parallel to each other, a plurality of second traces arranged in parallel to each other, a first touch electrode connected between the first traces, and a second touch electrode connected between the second traces, wherein the first traces and the second traces are intersected; the metal mesh is disposed on the surface of the insulation layer defining the grooves, the grooves are defined at an intersection of the first traces and the second traces, the first traces are disposed inside the grooves, and the second traces are disposed above the grooves; and
an insulating filling layer filled in the grooves and configured to insulatingly separate the first traces and the second traces.

11. The display device according to claim 10, wherein a cross section of each of the grooves is arc-shaped.

12. The display device according to claim 10, wherein an angle is included between each of the first traces and each of the second traces, and the angle ranges from 60° to 120°.

13. The display device according to claim 10, wherein structures of the first traces and the second traces are each a multilayer metal structure or a single-layer metal structure, and the multilayer metal structure comprises a titanium-aluminum-titanium structure; the single-layer metal structure comprises a silver nanowire structure or a copper wire structure.

14. The display device according to claim 10, wherein the insulating layer is a flexible inorganic layer, and material of the insulating layer comprises at least one of silicon nitride and aluminum nitride; the insulating filling layer is a flexible inorganic layer, and material of the insulating filling layer comprises at least one of silicon nitride and aluminum nitride.

15. The display device according to claim 10, further comprising a protective layer covering a surface of the metal mesh.
